(19) United States
(12) Patent Application Publication
(10) Pub. No.: US 2016/0114457 A1
(43) Pub. Date: Apr. 28, 2016

(54) UNIFORM POLISHING WITH FIXED ABRASIVE PAD

(71) Applicant: GLOBALFOUNDRIES Singapore Pte. Ltd., Singapore (SG)

(72) Inventors: Lup San LEONG, Singapore (SG); Cing Gie LIM, Singapore (SG); Wei LU, Singapore (SG); Ming ZENG, Singapore (SG); Alex SEE, Singapore (SG)

(21) Appl. No.: 14/522,593

(22) Filed: Oct. 24, 2014

(51) Int. Cl. B24B 37/26; H01L 21/306

(52) U.S. Cl. CPC B24B 37/26; H01L 21/30625

(57) ABSTRACT

A polishing pad for use in chemical mechanical polishing of a substrate is disclosed. The polishing pad includes first and second major surfaces. The first major surface forms a polishing surface and is divided into a main portion and edge portions. The edge portions are nearer to edges of the polishing pad while the main portion is between the edge portions and farther from the edges of the polishing pad. The polishing pad also includes a plurality of polishing posts disposed on the first major surface of the pad. The densities of the polishing posts in the edge portions and main portion are different.

### BACKGROUND

Fixed abrasive chemical mechanical polishing (CMP) has been widely used in semiconductor processing. A wafer may be polished using fixed abrasive CMP to produce a planar surface on a wafer. For example, fixed abrasive CMP may be employed to remove excess dielectric material in forming, for example, shallow trench isolation (STI) regions. However, we have observed that the use of fixed abrasive CMP frequently results in over-polishing or under-polishing at the wafer edge. This results in a non-planar surface across the wafer, particularly at the wafer edge. A non-planar surface negatively impacts yields.

From the foregoing discussion, there is a need to provide a method which prevents the above-mentioned phenomena at the wafer edge.

### SUMMARY

Embodiments generally relate to polishing pad for use in chemical mechanical polishing of a substrate, method of polishing, method of forming a semiconductor device and polishing tool. In one embodiment, a polishing pad for use in chemical mechanical polishing of a substrate is presented. The polishing pad includes first and second major surfaces. The first major surface forms a polishing surface and is divided into a main portion and edge portions. The edge portions are nearer to edges of the polishing pad while the main portion is between the edge portions and farther from the edges of the polishing pad. The polishing pad also includes a plurality of polishing posts disposed on the first major surface of the pad. The densities of the polishing posts in the edge portions and main portion are different.

In another embodiment, a method of forming a device is presented. The method includes providing a wafer substrate with a dielectric layer having topography and polishing the wafer substrate having the topography on a polishing pad. The polishing pad includes first and second major surfaces. The first major surface forms a polishing surface and is divided into a main portion and edge portions. The edge portions are nearer to edges of the polishing pad while the main portion is between the edge portions and farther from the edges of the polishing pad. The polishing pad also includes a plurality of polishing posts disposed on the first major surface of the pad. The densities of the polishing posts in the edge portions and main portion are different. The method further includes performing front end of line and back end of line processes to complete forming the device.

In yet another embodiment, a polishing tool is presented. The polishing tool includes at least one polishing station with a rotatable platen and a polishing unit mounted on the rotatable platen, wherein the polishing unit includes a polishing pad which includes first and second major surfaces. The first major surface forms a polishing surface and is divided into a main portion and edge portions. The edge portions are nearer to edges of the polishing pad while the main portion is between the edge portions and farther from the edges of the polishing pad. The polishing pad also includes a plurality of polishing posts disposed on the first major surface of the pad. The densities of the polishing posts in the edge portions and main portion are different.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the disclosure. In the following description, various embodiments of the present disclosure are described with reference to the following:

FIG. 1 shows an exemplary wafer;

FIG. 2 shows a simplified cross-sectional view of a wafer;

FIG. 3a shows an exemplary polishing tool;

FIGS. 3b-3c show exemplary fixed abrasive (FA) pad configurations;

FIGS. 3d-3e shows various positioning of a wafer carrier over an embodiment of a FA pad; and

FIGS. 4a-4d show simplified cross-sectional views of an embodiment of process 400 for forming STI regions on a wafer.

### DETAILED DESCRIPTION

Embodiments generally relate to devices, for example, semiconductor devices or integrated circuits (ICs). More particularly, embodiments relate to shallow trench isolations in ICs. The ICs can be any type of IC, such as dynamic or static random access memories, signal processors, microcontrollers or system-on-chip (SoC) devices. Other types of devices may also be useful. The devices or ICs can be incorporated into or used with, for example, consumer electronic products, or other types of products.

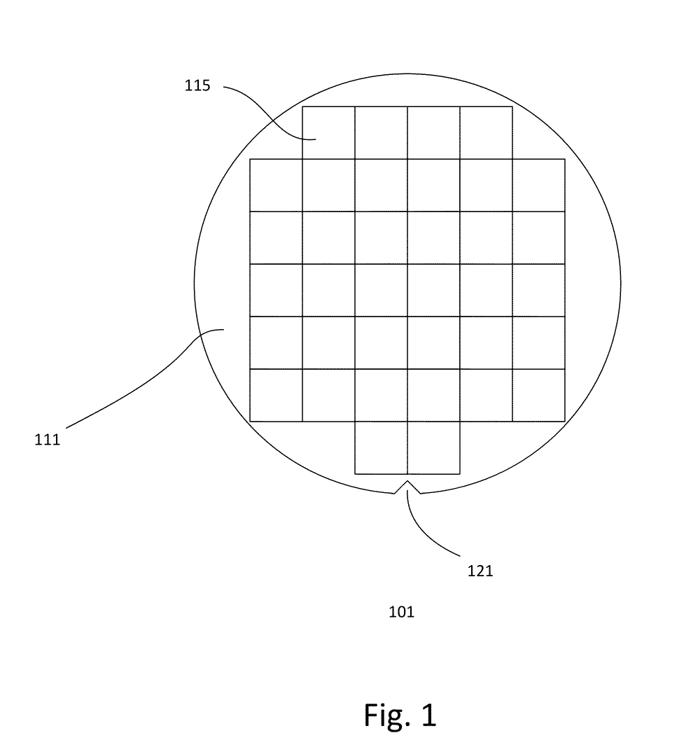

FIG. 1 shows a semiconductor wafer 101. The semiconductor wafer, for example, may be a silicon wafer. Other types of wafers are also useful. For example, the wafer may be a p-type, n-type, silicon-on-insulator (SOI) or silicon germanium wafer. The wafer may include a notch 121 to indicate the crystal orientation of the wafer. Other techniques for indicating the crystal orientation may also be useful. Additional indicators may also be included to indicate the dopant type of the wafer.

The wafer includes an active surface 111 on which devices 115 are formed. A plurality of devices may be formed on the wafer in parallel. The devices, for example, are arranged in rows along a first (x) direction and columns along a second (y) direction. After the devices are completed, they are subsequently singulated into individual dies, assembled and tested.

The fabrication of devices, such as integrated circuits (ICs), involves the formation of features on a substrate or wafer that make up circuit components, such as transistors, resistors and capacitors. Another type of feature is isolation regions. Isolation regions may be shallow trench isolation (STI) regions for isolating circuit components on the substrate surface within an IC. The components are interconnected, enabling the device to perform the desired functions. Interconnections are formed by forming contacts and conductive lines in a dielectric layer using, for example, damascene techniques. The features and interconnections are formed by repeatedly depositing and patterning layers on the wafer. The devices may have multiple interconnection layers. The structures of the different layers of the device are created or patterned using, for example, mask and etch techniques. Other techniques for patterning the different layers may also be useful.

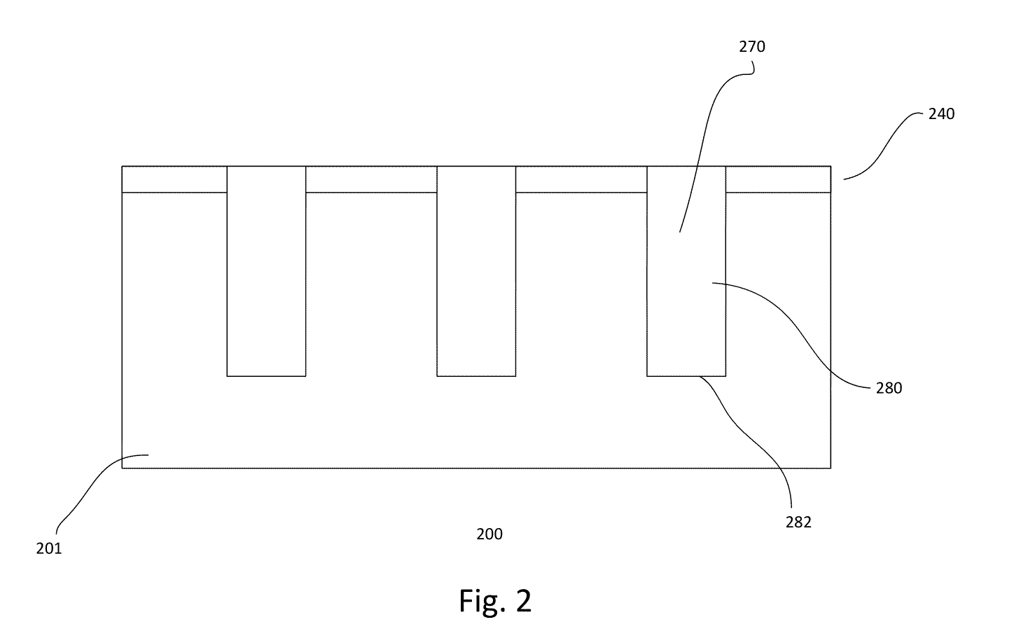

FIG. 2 shows a simplified cross-sectional view 200 of a wafer or substrate 201. As shown, the wafer is processed to include STI regions 280. The STI regions include trenches 282 in the substrate. The trenches may be etched by, for example, an anisotropic etch, such as a reactive ion etch (RIE) using a hard mask 240. The hard mask may be a silicon nitride layer. The nitride layer may include a pad oxide layer below. Other types of hard masks, including composite hard masks with multiple layers, may also be useful. The trench is filled with an isolation or dielectric material 270, such as silicon oxide. One or more isolation liners may be provided prior to filling the isolation trenches. Excess dielectric material are removed by a polishing process. In one embodiment, the polishing process includes chemical mechanical polishing (CMP). The polishing removes excess dielectric material over the hard mask, exposing it. The polishing process should result in, for example, coplanar top surfaces of the hard mask and STI regions.

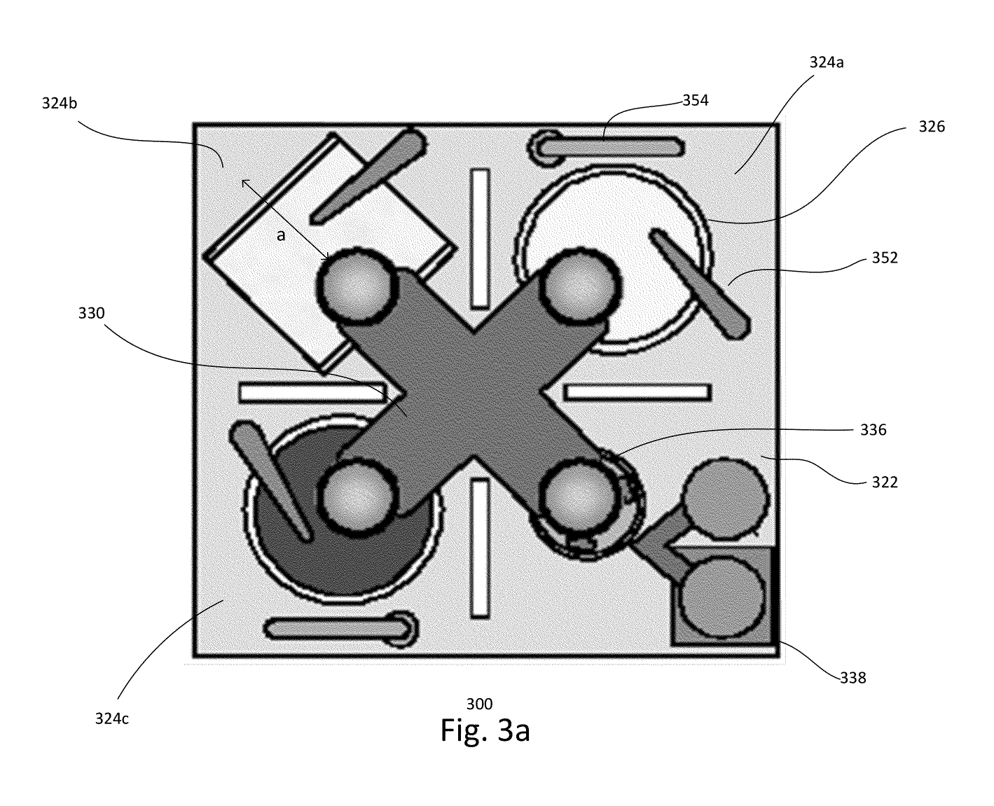

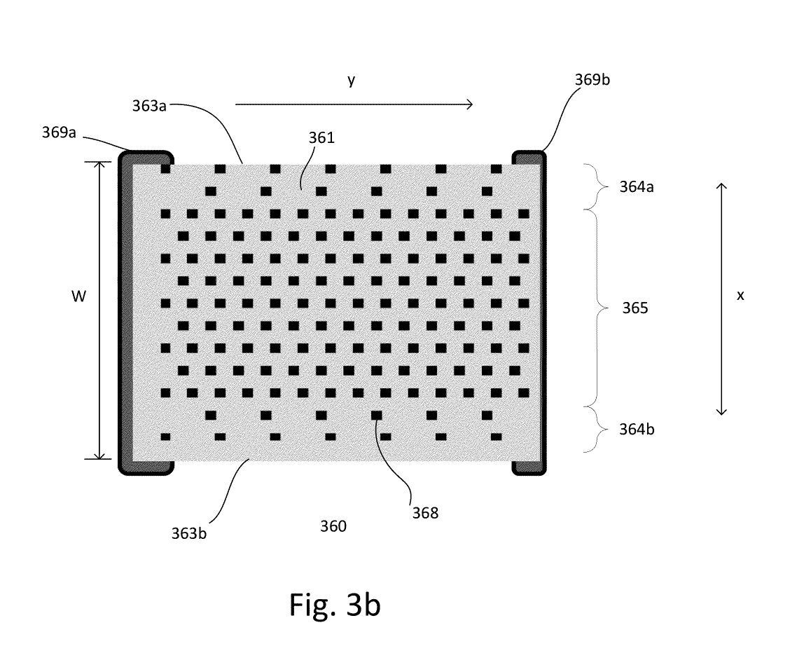

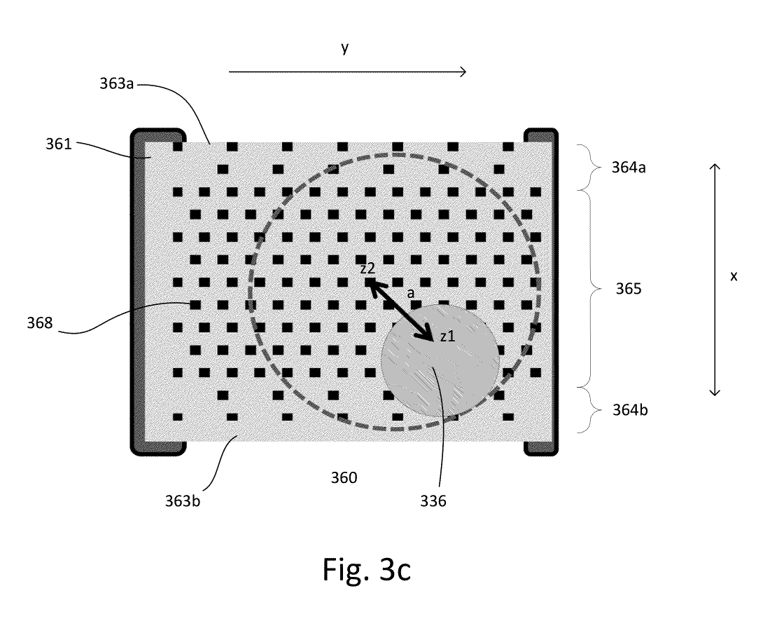

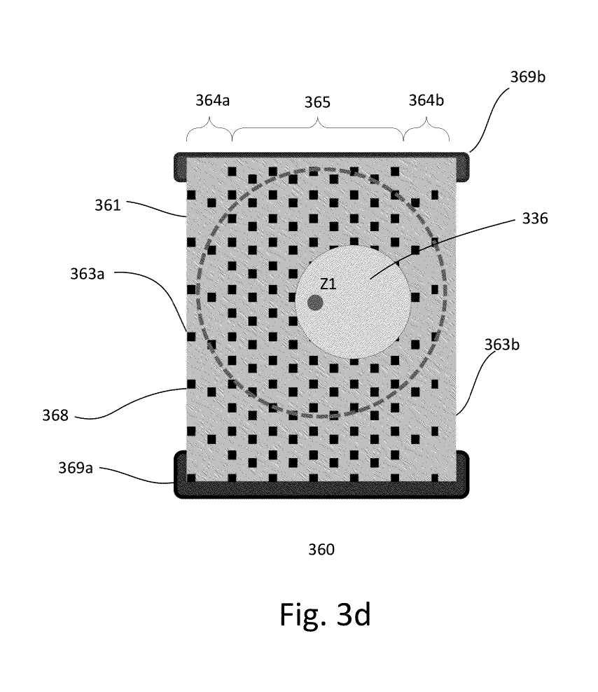

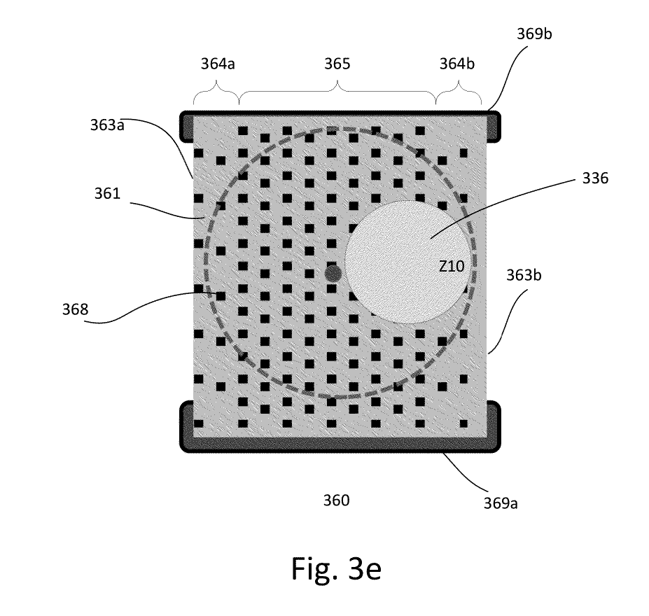

FIG. 3a shows an exemplary CMP tool 300 used in polishing a wafer. The tool includes a plurality of stations 324. As shown, the tool is provided with a loading station 322 and first, second and third polishing stations 324a-324c. The loading station includes a loader 338 for loading a wafer onto a polishing unit 336. The loader, for example, may be configured to load a wafer for polishing onto the polishing unit or remove the wafer from the polishing unit after polishing is completed. As for a polishing station, it includes a platen 326 on which a polishing pad is mounted, a slurry dispenser 352 for dispensing slurry which is used for polishing and deionized (DI) water which is used for cleaning the wafer. The polishing station also includes a pad conditioner 354 which is used to remove polishing debris and condition the pad to increase its lifetime. In some cases, adjacent stations may share a common pad conditioner. For example, as shown, the first and second polishing stations share a common pad conditioner.

A polishing unit 336 is provided for the CMP tool. The polishing unit is configured with polishing arms or extensions for the stations. For example, the polishing unit includes four polishing arms 330 arranged in a cross configuration, one for each station. The polishing unit is rotatable around a polishing unit axis, enabling the arms to rotate from one station to another. Other configurations of the polishing unit may also be useful. Wafer carriers are disposed at ends of the polishing arm. A wafer carrier holds a wafer in place for polishing. The wafer carrier may include pressure zones to selectively adjust pressure applied to the wafer onto the polishing pad during polishing. This may facilitate to produce the desired polishing profile. During polishing, the wafer carrier rotates, rotating the wafer against the polishing pad.

A polishing arm is configured to extend the wafer carrier along an extension direction away from the axis of rotation of the polishing unit, as indicated by arrow a. For example, the wafer carrier can translate along the extension direction. The carrier can be extended and retracted along the extension direction. The distance of travel by the carrier should be sufficient to enable uniform wearing of the polishing pad. For example, the distance of travel may be greater or slightly than needed to enable uniform wearing of the polishing pad.

In one embodiment, the travel distance should at least enable the carrier, in a retracted position, to have the wafer at the outer edge or circumference of the polishing pad and at an extended position, to have a center of the wafer at about the center of the polishing pad. For example, the travel distance should at least enable the wafer to travel the complete radius of the polishing pad. This facilitates more even wear on the polishing pad, increasing its lifetime.

During polishing, the CMP tool can program the carrier to translate along the extension direction. For example, the carrier can be programmed to travel between first (initial) and second (end) points along the extension direction. The distance of travel between end points is referred to as the swing distance. A swing sweep is the travel of the carrier from the initial point to the end point and back to the initial point. The speed of travel is referred to as swing rate. The swing rate, for example, may be constant. Alternatively, the swing rate may not be constant, depending on dwell time desired in different regions. The swing rate affects the dwell rate, or time which a wafer is polished by a specified portion of the polishing pad.

The different polishing stations perform different polishing functions. For example, the first polishing station 324a performs bulk polishing, the second polishing station 324b performs precise polishing which stops on the hard mask layer, such as the silicon nitride layer, with reduced dishing at STI, while the third polishing station 324c is a buffer station which provides low down force to smoothen the surface and removes artifacts and particles. Different types of slurry may be dispensed for the different stations during polishing by the slurry dispenser. Polishing may be performed in sequence from the first to the third polishing station. In one embodiment, the swing distance and swing rate are programmed to facilitate uniform wear of the polishing pad and/or uniform polishing profile on the wafer.

The CMP tool may include polishing stations with rotatable platens. For example, the first, second and third polishing stations include rotatable platens. Other configurations of polishing stations for the CMP tool may also be useful.

A rotatable platen, for example, has a circular shape. The rotatable platen rotates during polishing. For example, the rotatable platen may be rotated, for example, in the same direction as the wafer carrier. The first and third polishing stations, for example, include a circular polishing pad disposed on the rotatable platen. As for the second polishing station, it includes a fixed abrasive (FA) unit. The FA unit includes a FA magazine and FA pad. The FA magazine defines a polishing surface for the FA pad. The polishing surface, for example, may be a rectangular shaped polishing surface. Other polishing shaped surfaces may also be useful. The FA pad includes abrasive posts disposed on the polishing surface. The FA pad may be in the form of a roll. When a section of the pad is worn, the roll is rotated to translate a new unused section for polishing.

FIG. 3b shows an embodiment of a FA unit. The FA unit includes a FA magazine with a FA pad 360. Disposed on a first major surface of the FA pad are polishing posts 368. The first major surface serves as a polishing surface. The polishing posts may be arranged in an array pattern. The array pattern, for example, may be staggered, forming a checkered array pattern. Other suitable types of patterns for the posts may also be useful. The FA pad may be provided in the form of a roll. The width of the FA pad (W) may be, for example, about 700 mm. Other suitable widths for the FA pad may also be useful.

For example, a FA pad roll may be mounted onto the FA magazine. The FA magazine may include a frame with first and second end rollers 369a-369b. When the FA pad roll is mounted onto the FA magazine, the end rollers define or form a polishing surface 361. For example, the end rollers define ends of the polishing surface while sides of the FA pad 363a-363b define sides of the polishing surface. For example, first and second end rollers define first and second ends of the polishing surface while first and second sides of the FA pad defines first and second sides of the polishing surface. The polishing surface, for example, exposes the first surface of the pad with the polishing posts for polishing. As shown, the rollers form a polishing surface having a rectangular shape. Other suitable shapes may also be useful.

The roll of FA pad may be mounted onto a supply roller disposed at about a first end of the frame. An exposed end of the FA pad on the supply roller may be routed through the end rollers and attached to a take up roller located at about a second end of the frame. It is understood that the supply and take up rollers need not be aligned with first and second end rollers. Other configurations of rollers or FA magazines may also be useful. For example, the end rollers may serve as supply and take up rollers. The take up roller may be rotated, translating the FA pad to remove a worn portion unsuitable for polishing and provide un-used portion for polishing from the supply roller. For example, the FA pad is translated in a direction as indicated by the y-arrow. This moves the worn portion to or towards the second end roller.

In one embodiment, the polishing pad along the width direction (x) is divided into a main portion 365 disposed between edge portions 364a-364b. For example, the edge portions are from edges of the FA pad along the direction of translation while the main portion is between them. The edge portions are configured to produce uniform wafer surface from polishing. For example, the edge portions are configured to reduce over polishing at the edge of the wafer. A width of the edge portions may be about 5-20 cm for a 300 mm wafer. Other suitable widths of edge portions may also be useful. The width may differ depending on the size of the wafer. Other factors, such as pattern density and polishing pressures, may also affect the width of the edge portions.

Polishing posts are distributed in the portions of the FA pad. The polishing posts are distributed evenly in the portions of the FA pad. In one embodiment, the density of polishing posts in the edge portions and main portion are different. The polishing rate is affected by the density of polishing posts, assuming other parameters, such as rotational velocity and pressure, are constant. For example, for a given set of polishing parameters, the density of polishing posts affects polishing rate. In particular, the polishing rate is directly related to the density of the polishing posts. For example, the higher the density of polishing posts, the higher the polishing rate. Conversely, the lower the density of polishing posts, the lower the polishing rate. The difference in density of the polishing posts in the edge and main portions should be selected to reduce under-polish or over-polish at the wafer edge. Preferably, the density of the polishing posts in the edge portions are the same. This, for example, is due to edge portions of the FA pad affect polishing of the edge portions of the wafer. Providing edge portions of the FA pad with different densities of polishing posts may also be useful.

In the case where over-polishing of wafer edge is a problem, the FA pad is configured with polishing posts in the edge portions having a density which is less than that in the main portion. The main density of polishing posts in the main portion may be about 15-20%. For the edge portions, the edge density of polishing posts may be about 5-10%. Providing other suitable densities for the main and edge portions may also be useful. The density difference of polishing posts in the main and edge portions should be sufficient to facilitate reduction of polishing rate at the wafer edge. Reducing the polishing rate at the wafer edge improves polishing uniformity across the wafer.

On the other hand, the density of polishing posts may be higher at the edge portions than the main portion to reduce under-polishing at the wafer edge. The density of polishing posts in the main portion may be about 15-20% while in the edge portions may be about 20-30%. Providing other suitable densities of polishing posts for the main and edge portions may also be useful. The density difference should be sufficient to facilitate an increase in polishing rate at the wafer edge. Increasing the polishing rate at the wafer edge improves polishing uniformity across the wafer.

FIG. 3c shows a FA unit with a FA pad 360. The FA unit is similar to that described in FIG. 3b. Common elements may not be described or described in detail. The FA unit is mounted on a rotatable platen as illustrated by a dotted line. The rotatable platen, for example, rotates during polishing. The FA unit, for example, may be rotating at about 15-40 rpm. The rotatable platen may be rotated, for example, in the same direction as the wafer carrier.

The wafer carrier 336 can be configured to translate along arrow a between points z1 and z2. For example, z1 may be a minimum retracted point of the carrier arm and z2 may be a maximum extended point of the carrier arm. The swing or sweep distance is the distance that the carrier arm is programmed to travel between z1 and z2. The swing distance may not be from the maximum to the minimum refracted positions z1 and z2. For example, the swing distance may be somewhere between z1 and z2. For example, the swing distance is from an initial swing position to an end position which may be between z1 and z2. The initial and end position may include z1 or z2. This ensures that the wafer can travel the desired swing distance, with a buffer for alignment purposes, increasing processing window.

The polishing recipe can be tailored to produce a desired polishing profile. In one embodiment, the sweep profile, such as sweep speed and sweep distance, is tailored to produce a desired polishing profile. In one embodiment, the sweep profile is tailored to produce a uniform polishing profile. For example, the polishing profile is in a planar or substantially planar surface. The sweep profile may include different concentric polishing zones within the polishing portion of the polishing surface. The innermost polishing zone, for example, may be Z1 while the outermost zone may be Zm, where m is the number of zones. In the case of 10 zones, the outermost zone is Z10. Other number of zones may also be useful. The outermost zone, for example, may correspond to an outer edge of the wafer while the innermost zone Z1 may correspond to the inner edge of the wafer.

The sweep profile, such as sweep rate, for example, may be tailored to control the dwell time of the wafer in the individual zones. For example, the sweep rate may be tailored so that the dwell time of the wafer in the different polishing zones produces a desired polishing profile. The swing rate can be tailored so that the dwell time in the different zones of the polishing pad produces the desired polishing profile. The desired polishing profile, for example, is a planar polishing profile. Other suitable profiles may also be useful. The desired polishing profile can be achieved without the need of pressure adjustments on the wafer carrier. Of course, pressure adjustments may be employed to augment or tune the present FA pad to achieve the desired polishing profile.

As described, the FA pad enables polishing a wafer to achieve the desired polishing profile. For example, providing edge and main portions with different post densities enables the desired profile to be achieved. Further, the desired polishing profile may be achieved by tailoring the swing distance and swing rate of the wafer carrier across the pad. By configuring the sweep rate and the start and end point of the sweep, any suitable software can be used to calculate or predict the dwell time of the edge vs. the center of the wafer. From there, we can configure or change the polishing profile.

As an example, a sweep profile may include 10 polishing zones, with zone Z1 corresponding to the center of the wafer, as shown in FIG. 3d and zone Z10 corresponding to an edge of the wafer, as shown in FIG. 3e. FIGS. 3d-3e is similar to that shown in FIG. 3c. Common elements may not be described or described in detail. For example, FIG. 3d illustrates a wafer carrier 336 positioned such that Z1 is polishing the inner edge of a wafer while FIG. 3e illustrates the wafer carrier 336 in position to polish an outer edge of the wafer. For example, Z10 correspond to an edge portion of the polishing pad 360.

Assume a pad having edge portions with 5% post density and a main or bulk portion with 10% density is used to polish a wafer. For purpose of illustration, assume that such a pad produces an etch rate in the main portion which is twice that of the edge portions. This results in an effective polishing rate at the wafer edge to be about 75% of that in the other portions of the wafer. This is because, with a rotating FA unit, 2 out of 4 sides of the FA polishing surface will have 50% of the etch rate as the bulk while the other two sides will be equal to that of the bulk. By providing a dwell time in Z10 which is twice that at other zones should produce a wafer having a planar or uniform polishing profile across the wafer.

The sweep profile may be defined, for example, using a user interface (UI) of a controller for programming the CMP tool. Various sweep parameters or patterns may be provided as input to the UI. Based on the sweep parameter inputs, the controller calculates the dwell time of the different zones for polishing. For example, the controller determines the dwell time of different zones based on the sweep parameter inputs. Thus, dwell time of individual zones can be independently controlled. The desired polishing profile may be achieved without adjusting pressure applied to different regions of the wafer by the wafer carrier. Avoiding the need to adjust pressure applied to different regions of the wafer advantageously prevents life reduction of the pad or retaining ring if pressure is added while prevents wafer slippage if reduced pressure is applied. Of course, the pressure adjustments may be available to augment the effects of the FA pad.

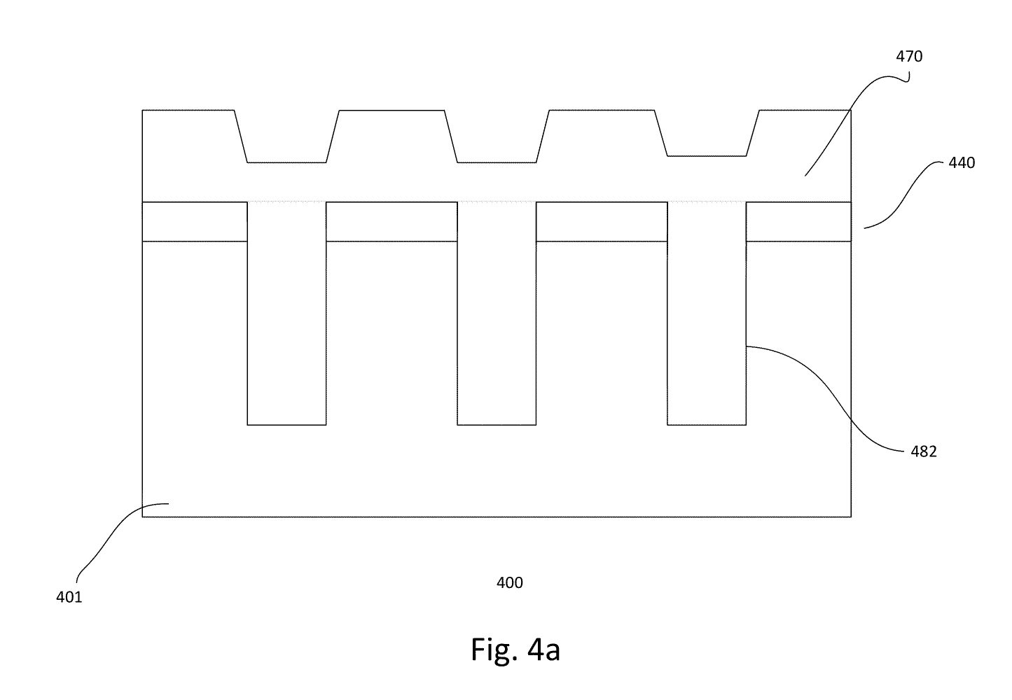

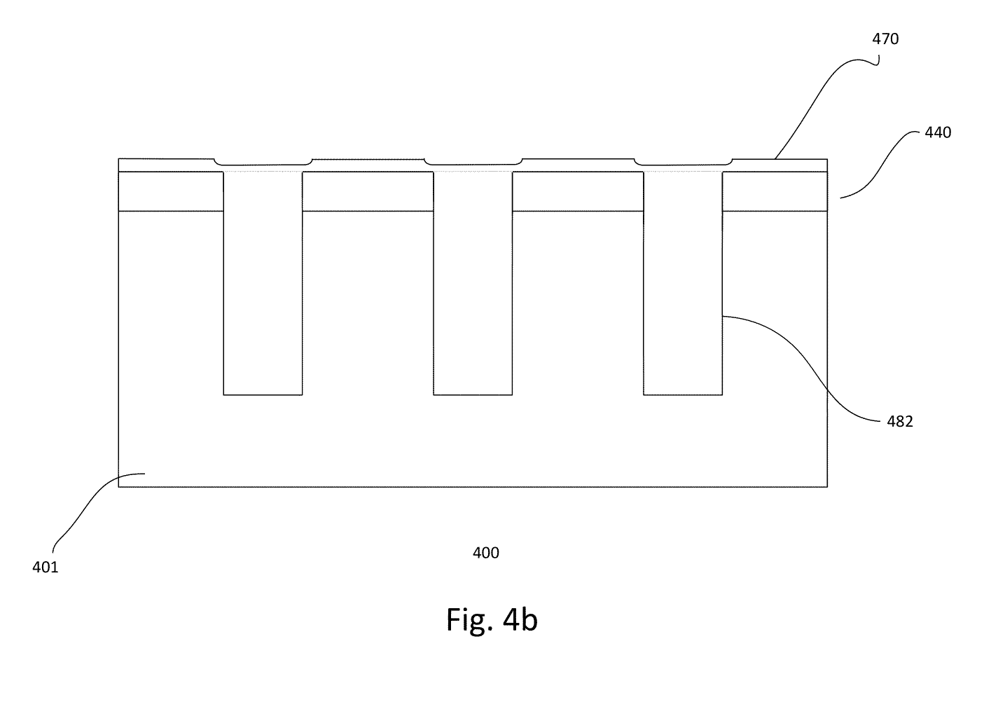

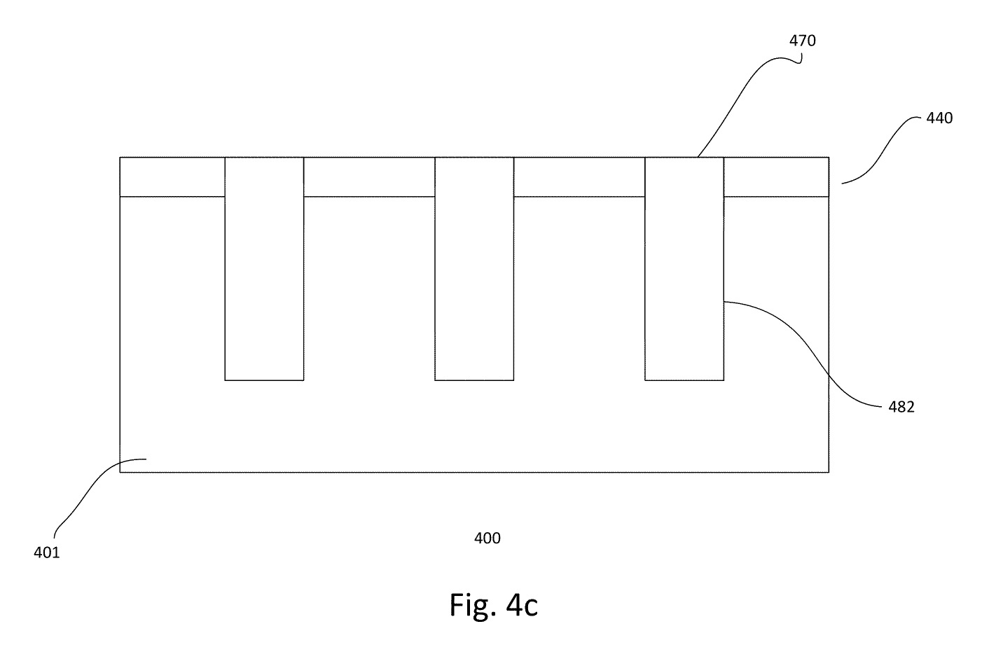

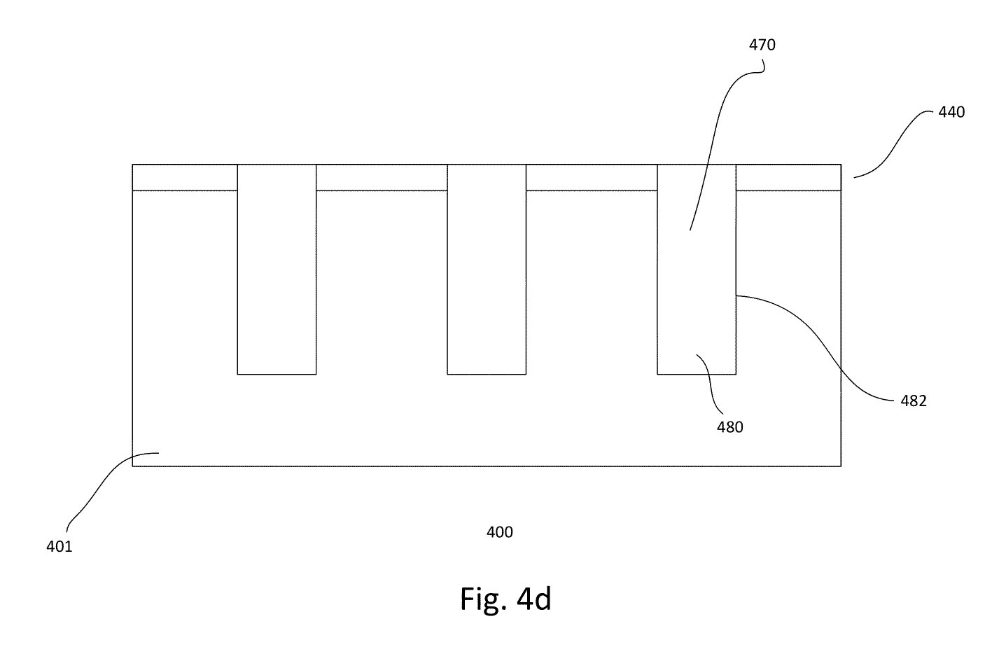

FIGS. 4a-4d show simplified cross-sectional views of an embodiment of process 400 for forming devices on a wafer. In particular, the process illustrates forming isolation regions of devices on a wafer. The isolation regions are STI regions. The isolation regions may be similar to those described in FIG. 2. Common elements may not be described or described in detail.

Referring to FIG. 4a, a wafer or substrate 401 is provided. The wafer is a semiconductor wafer, such as a silicon wafer. Other types of wafers are also useful. For example, the wafer may be a p-type, n-type, silicon-on-insulator (SOI) or silicon germanium wafer. The wafer includes an active surface on which devices are formed. As previously described, a plurality of devices may be formed on the wafer in parallel.

As shown, the wafer is prepared with isolation trenches 482 formed in the substrate. The isolation trenches should have a width and depth sufficient to provide the isolation of circuit components. The isolation trenches may be formed by, for example, mask and etch techniques. In one embodiment, a hard mask 440 is provided on the wafer. The hard mask is patterned to form openings corresponding to isolation trenches. The hard mask may be a silicon nitride layer. The nitride layer may include a pad oxide layer below. Other types of hard masks, including composite hard masks with multiple layers, may also be useful.

The hard mask is patterned by a soft mask, such as photoresist. The soft mask is selectively exposed by an exposure source using a reticle and developed to produce the desired pattern corresponding to the reticle. To improve lithographic resolution, an anti-reflective coating (ARC) layer may be provided beneath the soft mask. The patterned soft mask includes openings corresponding to the isolation trenches. The pattern of the soft mask is transferred to the hard mask using an anisotropic etch, such as a reactive ion etch (RIE). After patterning the hard mask, the soft mask may be removed by, for example, ashing. The wafer is etched by an anisotropic etch, such as RIE, using the hard mask as an etch mask to form isolation trenches.

A dielectric layer 470, such as silicon oxide, is deposited on the substrate, filling the trenches and covering the hard mask. The dielectric layer may be formed by, for example, a high aspect ratio process (HARP). Forming the dielectric layer using other techniques may also be useful. One or more isolation liners may be provided to line the isolation trenches prior to forming the dielectric layer. The liners, for example, may include SiN. Other suitable types of liner material may also be useful. The liners may serve to protect the silicon substrate during etching of the trenches. The dielectric layer is conformal or essentially conformal, creating topography. For example, raised portions are formed over the hard mask and recessed portions are formed over the trenches.

Referring to FIG. 4b, a polishing process is performed on the substrate. In one embodiment, a first polishing process is performed. The polishing process, for example, includes CMP. In one embodiment, a first CMP process is performed by the first polishing station 324a. The polishing process removes a majority or bulk portion of the excess dielectric layer. The majority portion may be removed by the first polishing or coarse polishing station. The first CMP process reduces the height of the excess dielectric layer. For example, a small amount of dielectric layer remains, having a top surface over the hard mask and trenches above the top surface of the hard mask. As shown, the topography, although reduced by the first CMP process compared to that shown in FIG. 4a, remains. The remaining dielectric layer, for example, includes thickness of about 500-2000 Å. Other suitable thickness may also be useful for the remaining dielectric layer.

In one embodiment, as shown in FIG. 4c, a second polishing process is performed. The second polishing or CMP process, for example, includes a precise polishing process. The second polishing process may be performed by the second polishing station. The second polishing process is performed on a fixed platen using a FA pad, as described herein. For example, the FA pad includes edge portions having a different post density than that of the main portion. Providing edge and main portions with different post densities improves polishing profile uniformity across the wafer.

In one embodiment, the polishing with FA pad is tailored to produce a uniform polishing profile. The polishing recipe includes tailoring the swing distance and swing rate of the carrier head to produce the desired polishing profile. For example, the swing distance and swing rate are tailored to produce a uniform polishing profile across the wafer. The swing rate controls the dwell time of the wafer at a region of the pad. The swing rate can be tailored to reduce over-polishing or under-polishing at the wafer edge.

The polishing by the FA pad, in one embodiment, produces a uniform profile across the wafer. The polishing, for example, produces a uniform planar surface between the STI regions and hard mask. In one embodiment, the polishing uses the hard mask as a polishing stop. For example, the polishing stops at about the hard mask, producing a uniform planar surface between the STI region and hard mask.

Referring to FIG. 4d, a third polishing process is performed. For example, the third CMP process is performed by the third polishing station or buffer station. The third CMP process polishes the wafer, removing portions of the STI regions and hard mask. The third CMP process produces a uniform planar surface between the STI region and hard mask. In one embodiment, an amount of material removed by the third polishing process subsequently results in the desired profile between the STI regions and wafer surface after removal of hard mask and deglazing.

The process continues to form devices on the wafer. For example, front end of line processes are performed to form transistors and other components followed by back end of line processes to form interconnections in metal layers. After completing the devices, the wafer is diced to separate the devices. The devices may be assembled into packages and tested. Other processes may also be included.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1-9. (canceled)

10. A method of forming a device comprising:
providing a wafer substrate with a dielectric layer having topography;
polishing the wafer substrate having the topography on a polishing pad which comprises
first and second major surfaces, wherein the first major surface forms a polishing surface and is divided into a main portion and edge portions, wherein the edge portions are nearer to edges of the polishing pad while the main portion is between the edge portions and farther from the edges of the polishing pad, and
a plurality of polishing posts disposed on the first major surface of the pad, wherein densities of the polishing posts in the edge portions and main portion are different; and
performing front end of line and back end of line processes to complete forming the device.

11. The method of claim 10 wherein polishing the wafer substrate comprises translating the wafer substrate on the polishing surface by swinging the wafer substrate, wherein swing speed and swing distance of the wafer substrate across the polishing pad is defined to produce a desired polishing profile.

12. The method of claim 11 wherein the swing speed and swing distance are defined such that dwell time of the wafer substrate at different zones on the polishing pad is individually controlled.

13. The method of claim 10 wherein the densities of the polishing posts in the edge portions are the same.

14. The method of claim 10 wherein the densities of the polishing posts in the edge portions are different.

15. The method of claim 10 wherein the density of the polishing posts in the edge portion is less than the density of the polishing posts in the main portion to reduce over-polishing of edge of the wafer substrate.

16. The method of claim 15 wherein the density of the polishing posts in the edge portion is about 5-10% and the density of the polishing posts in the main portion is about 15-20%.

17. The method of claim 10 wherein the density of the polishing posts in the edge portion is higher than the density of the polishing posts in the main portion to reduce under-polishing of edge of the wafer substrate.

18. The method of claim 17 wherein the density of the polishing posts in the edge portion is about 20-30% and the density of the polishing posts in the main portion is about 15-20%.

19. The method of claim 10 wherein the polishing pad is provided in the form of a roll having first and second rollers, wherein the first roller contain the roll of the polishing pad and an exposed end of the polishing pad is fitted to the second roller.

20. (canceled)

21. The method of claim 10 wherein the polishing posts are distributed evenly in the respective portions of the polishing pad.

22. The method of claim 10 wherein the polishing pad is provided in a fixed abrasive (FA) unit of a polishing tool, wherein the polishing pad is provided in a form of a FA pad roll mounted onto a FA magazine having a frame and first and second end rollers.

23. The method of claim 22 wherein the FA unit is mounted on a rotatable platen.

24. The method of claim 10 wherein the wafer substrate is prepared with isolation trenches corresponding to shallow trench isolation (STI) regions formed in the substrate, a hard mask formed over the wafer substrate and the dielectric layer having the topography disposed over the hard mask and filling the isolation trenches.

25. The method of claim 24 wherein polishing the wafer substrate comprises removing excess dielectric layer over the hard mask by translating the wafer substrate on the polishing surface by swinging the wafer substrate, wherein swing speed and swing distance of the wafer substrate across the polishing pad are tailored to produce a uniform polishing profile across the wafer substrate.

26. The method of claim 25 wherein the swing speed and swing distance of the wafer substrate across the polishing pad are tailored to produce a uniform planar surface between the STI regions and the hard mask without adjusting pressure applied to different regions of the wafer substrate.

27. The method of claim 25 wherein the swing speed is tailored to reduce over-polishing or under-polishing at an edge of the wafer substrate.

28. The method of claim 27 wherein the density of the polishing posts in the edge portion is less than the density of the polishing posts in the main portion to reduce over-polishing of the edge of the wafer substrate.

29. The method of claim 27 wherein the density of the polishing posts in the edge portion is higher than the density of the polishing posts in the main portion to reduce under-polishing of the edge of the wafer substrate.

30. The method of claim 25 wherein the swing speed and swing distance are defined such that dwell time of the wafer substrate at different zones on the polishing pad is individually controlled.
